(19) United States
(12) Patent Application Publication
(10) Pub. No.: US 2007/0167003 A1
(43) Pub. Date: Jul. 19, 2007

(54) Adhesive film and method for forming metal film using same

(75) Inventors: Yoshihisa Saimoto, Nagoya-shi (JP); Makoto Kataoka, Sodegaura-shi (JP); Kouji Igarashi, Nagoya-shi (JP); Shinichi Hayakawa, Nagoya-shi (JP)

Correspondence Address: BUCHANAN, INGERSOLL & ROONEY PC, POST OFFICE BOX 1404, ALEXANDRIA, VA, 22313-1404, US

(73) Assignee: MITSUI CHEMICALS, INC., Minato-ku, Tokyo (JP)

(21) Appl. No.: 10/569,940

(22) PCT Filed: Aug. 31, 2004
(86) PCT No.: PCT/JP04/12506

§ 371 Date: Nov. 9, 2006

(30) Foreign Application Priority Data
Sep. 1, 2003 (JP) 2003-308174
Nov. 26, 2003 (JP) 2003-394836

(51) Int. Cl. H01L 21/44

(52) U.S. Cl. 438/653

(57) ABSTRACT

The present invention relates to an adhesive film capable of preventing damage to a non-metal-film-formed surface when forming a metal film on a semiconductor wafer and further capable of reducing contamination on the wafer surface. The adhesive film comprises a base film laminated with at least one film layer having a gas transmission rate of not more than 5.0 cc/m²·day·atm with an adhesive layer formed on one surface thereof. By protecting the non-metal-film-formed surface, a washing step using a solvent can be omitted and contamination on the non-metal-film-formed surface can also be reduced, thus resulting in enhancement of productivity and workability.

### FIELD OF INVENTION

The present invention relates to an adhesive film for forming a metal film on a non-circuit-formed surface of a semiconductor wafer. More specifically, the invention relates to an adhesive film which suppresses damage to a non-metal-film-formed surface or contamination on the wafer during formation of a metal film, and a method for forming a metal film using the adhesive film. According to the present invention, a process for washing the non-metal-film-formed surface can be omitted, thus realizing a rationalization of the manufacturing process and improvement of productivity

### BACKGROUND ART

A process which includes grinding a semiconductor wafer at a surface at which no circuit is provided (hereinafter, such a surface is referred to as a “back surface of a semiconductor wafer”) and forming a metal film on the back surface can be cited as one example of high temperature treatments in semiconductor production processes.

Conventionally, a metal film had been formed on a back surface of a semiconductor wafer by a method including grinding a semiconductor wafer, to which is attached a surface protecting adhesive film, to a thickness of around 300 μm and peeling the surface protecting adhesive film away therefrom. However, recently, technological innovation in processes for producing semiconductor wafers has advanced together with miniaturization and increased functionalization of devices, and processes for producing semiconductor wafers to accommodate ultra thin chips are changing. In these circumstances, materials for protecting a surface of a semiconductor wafer supporting an ultra thin semiconductor wafer have been under intensive development. For example, a resin composite inorganic substrate obtained by impregnating and curing a heat resistant resin as a support material is disclosed in Japanese Patent Application Laid-Open (JP-A) No. 2001-77304A. However, the support material requires investment in facilities for attaching the substrate to the semiconductor wafer. Further, the attachment method is a thermal compression bonding method requiring high temperature conditions. Since such a support material is peeled away at a high temperature using water vapor or the like, there are problems in that, for example, devices on the surface of the semiconductor wafer might be broken.

On the other hand, as a method for preventing damage or contamination on the non-metal-film-formed surface, a method comprising applying a member such as a resist is known. However, in this method, a step of removing the resist on the non-metal-film-formed surface with a solvent or the like after forming a metal film is required, and this poses a big obstacle in terms of productivity from the viewpoints of complexity of operations and environmental problems. Furthermore, in recent years, the shapes of adherends for forming a metal film have diversified, the surfaces of non-metal-film-formed surfaces have become complicated, and there are cases when the resist might remain on the non-metal-film-formed surface even after it is washed with a solvent. Furthermore, the adherend itself becomes thinned. Accordingly, it has been pointed out that when the resist or the like is unevenly applied, the adherend might be damaged or broken at the time of forming a metal film. Instead, members capable of easily protecting the non-metal-film-formed surface are in high demand.

### DISCLOSURE OF THE INVENTION

An object of the present invention is to provide an adhesive film capable of suppressing damage to and contamination on a non-metal-film-formed surface when forming a metal film on a non-circuit-formed surface of a semiconductor wafer in a semiconductor production process and capable of further rationalizing the process of forming a metal film, and to provide a method for forming a metal film using the adhesive film.

The present inventors have conducted extensive research and, as a result, have found that an adhesive film using a base film laminated with at least one film layer having a gas transmission rate of not more than 5.0 cc/m²·day·atm is the most suitable for protecting a non-metal-film-formed surface at the time of forming a metal film. Thus, the present invention has been completed.

That is, a first aspect of the present invention is a method for forming a metal film on a non-circuit-formed surface of a semiconductor wafer, wherein the metal film is formed by attaching an adhesive film, in which an adhesive layer is formed on one surface of a base film comprising at least one film layer having a gas transmission rate of not more than 5.0 cc/m²·day·atm, to a circuit-formed surface of a semiconductor wafer (a non-metal-film-formed surface).

It is preferable that the base film comprises a metal film layer or a metal oxide film layer, and at least one film layer having a gas transmission rate of not more than 5.0 cc/m²·day·atm. This is because out-gas from the adhesive film in a process for forming a metal film can be reduced thereby.

Furthermore, it is preferable that the base film comprises at least one film layer having a gas transmission rate of not more than 1.0 cc/m²·day·atm and water absorptance of not more than 1.0 weight %. This is because the time taken to reach initial (blank) vacuum level can be reduced in a process for forming a metal film.

Furthermore, it is preferable that the base film further comprises one film layer selected from an ethylene-vinyl acetate copolymer, polyester and polyethylene. This is because such a base film is capable of providing support properties and/or cushion properties in order to prevent breakage of the semiconductor wafer.

It is preferable that the adhesive layer has a storage elastic modulus of not less than 1×10⁵ Pa at 150° C. This is because adhesive residue on the semiconductor wafer after the adhesive film is peeled away can be prevented.

A second aspect of the invention is an adhesive film for forming a metal film on a non-circuit-formed surface of a semiconductor wafer, wherein an adhesive layer is formed on one surface of a base film comprising at least one film layer having a gas transmission rate of not more than 5.0 cc/m²·day·atm.

It is preferable that a base film comprises at least one film layer having a gas transmission rate of not more than 1.0 cc/m²·day·atm and water absorptance of not more than 1.0 weight %. This is because out-gas from the adhesive film can be reduced and the time taken to reach inital (blank) vacuum level can be shortened in a process for forming a metal film. By using the adhesive film according to the present invention, damage to the non-metal-film-formed surface can be suppressed when forming a metal film and productivity can be enhanced. Furthermore, since contamination on the non-metal-film-formed surface can be suppressed, a step of washing with a solvent can be omitted, and thus improvement in workability can also be achieved.

### BEST MODE FOR CARRYING OUT THE INVENTION

Hereinafter, the present invention will be described in more detail.

A method for protecting the non-metal-film-formed surface of a non-circuit-formed surface of a semiconductor wafer at the time of forming a metal film will first be explained.

Firstly, the adhesive film of the present invention is applied to the non-metal-film-formed surface of the semiconductor wafer via an adhesive layer. Subsequently, the adherend attached to the adhesive film is placed on a metal film forming device to form a film made of a metal on a surface to which the adhesive film is not attached. Then, the adhesive film is peeled away and a metal-film-formed adherend is obtained. The adherend is appropriately processed thereafter.

Conditions to form a film made of a metal are different depending on metal species (such as gold, nickel, titanium or the like) and methods for forming a film (such as metal evaporating method, metal sputtering method or the like). However, a metal film is formed at a temperature of from 50° C. to 200° C. under a pressure of from 10⁻³ to 10⁻⁷ Pa.

The operation of attaching the adhesive film to the semiconductor wafer is automatically conducted by using an adhering machine comprising a roll-shaped adhesive film, although it may be manually operated in some cases. The non-metal-film-formed surface is washed as required after the adhesive film is peeled away. As the washing method, wet washing such as water washing or dry washing such as plasma washing and the like may be carried out. In the wet washing, ultrasonic washing may be used in combination. These washing methods are appropriately selected depending on the state of contamination on the non-metal-film-formed surface.

Next, the adhesive film according to the present invention will be explained.

The adhesive film according to the present invention is produced by preparing a base film and forming an adhesive layer on one surface of the base film. An adhesive film with a release film attached to the adhesive layer is preferable from the viewpoint of prevention of contamination of the adhesive layer. The adhesive film is adhered to an adherend via the surface of the adhesive layer that is exposed after peeling off the release film. When the release film is to be laminated, in order to prevent the contamination of the adhesive layer, it is preferable that the adhesive agent coating solution is applied on one surface of the release film and dried to form an adhesive layer, and then the thus-formed adhesive layer is transferred to one surface of the base film.

The base film used for the adhesive film of the present invention is a base film laminated with at least one film layer having a gas transmission rate of not more than 5.0 cc/m²·day·atm. The gas transmission rate is preferably not more than 1.0 cc/m²·day·atm, and the water absorptance is preferably not more than 1.0 weight % and more preferably not more than 0.1 weight % in view of the fact that the time for reaching initial vacuum level in the process for forming a metal film can be shortened thereby. A base film comprising at least one film layer having a gas transmission rate of not more than 5.0 cc/m²·day·atm is preferable because an effect of reducing out-gas from the adhesive film is exhibited, the state of the metal-formed surface becomes favorable, and as a result, electrical properties after mounting on a semiconductor wafer become favorable. Out-gas is considered to be generated from a side of the adhesive film, i.e., an edge of the semiconductor wafer with the adhesive film attached thereto, and from a main surface of the base film. By limiting the gas transmission rate of the base film, out-gas from the main surface of the base film can be shielded so that there is a significant effect of reducing out-gas. Furthermore, due to this effect, the time for reaching initial vacuum level can be shortened in the process for forming a metal film, leading to enhancement in the operational workability as well. Furthermore, it is possible to prevent the formation of a metal film in a state where the vacuum level has not been reached due to the generated out-gas in a process for forming a metal film, and it is also possible to prevent bad formation of a film caused by the generated out-gas during the formation of a metal film. Examples of films satisfying these physical properties include films having a metal film layer or a metal oxide film layer, and liquid crystalline polymer films. Furthermore, base films having these films laminated with a film selected from an ethylene-vinyl acetate copolymer, polyester, polyethylene or the like can also be used. However, in this case, considering the temperature and vacuum conditions in the process for forming a metal film, a preferable film construction has a film layer having a gas transmission rate of not more than 5.0 cc/m²·day·atm placed at the outermost layer of the base film, not in the adhesive layer side.

Typical examples of the metal film include a vapor deposited film of metals such as aluminum and the like, and examples of a metal oxide film include an oxide film of metals such as silicon, titanium, and aluminum.

As a method for forming a metal oxide film layer, there can be exemplified a method comprising coating or evaporating an oxide such as silicon, titanium, aluminum or the like on a film such as polyester, including polyethyleneterephthalate and the like. The thickness of the metal layer and the metal oxide film layer is preferably from 1 nm to 50 nm and more preferably from 1 nm to 30 nm.

The thickness of the film is preferably from about 10 μm to 200 μm. Furthermore, the thickness of a composite base film laminated with a film selected from an ethylene-vinyl acetate copolymer, polyester and polyethylene is preferably from about 50 μm to 300 μm.

As a metal vapor deposited film, a vapor deposition processed film manufactured by Tohcello Co., Ltd. or the like can be cited. As a metal oxide film vapor deposited film, TECHBARRIER (trade name, manufactured by Mitsubishi Plastics, Inc.) or the like can be cited. As a liquid crystalline polymer film, VECSTAR (trade name, manufactured by Kuraray Co., Ltd.), BIAC® (trade name, manufactured by Japan Goretech or the like can be cited. As polyester, TEONEX and TETORON (both trade names, manufactured by Teijin Du pont Films Ltd.) can be cited.

The adhesive agent forming the adhesive layer of the adhesive film according to the present invention is acceptable insofar as it functions as an adhesive agent even under the temperature conditions at the time of forming a metal film. As for desirable adhesive agents, there can be exemplified an acrylic adhesive agent and a silicon adhesive agent. The thickness of the adhesive layer is preferably from 3 μm to 100 μm. When the adhesive film is peeled away, it is preferable that an adhesive agent causes no contamination on the non-metal-film-formed surface.

In particular, it is preferable that the adhesive agent is cross-linked with a cross-linking agent having a reactive functional group, a peroxide, radioactive rays or the like at a high density lest the adhesive strength be increased too much through exposure to the high temperature in the metal film forming process and contamination on the non-metal-film-formed surface be increased. The storage elastic modulus of the adhesive layer at 150° C. is preferably not less than 1×10⁵ Pa and more preferably not less than 1×10⁶ Pa. Furthermore, the storage elastic modulus of the adhesive layer at 200° C. is preferably not less than 1×10⁵ Pa and more preferably not less than 1×10⁶ Pa.

Hereinafter, as a method for forming an adhesive layer, a method using an acrylic adhesive agent is exemplified. However, the present invention is not restricted to such a method.

The adhesive layer is formed by using a solution or an emulsion in which a cross-linking agent having two or more functional groups in a molecule is added to a copolymer which is obtained by performing an emulsion polymerization of a (meth)acrylic acid alkyl ester monomer unit (A), a monomer unit (B) having a functional group capable of reacting with a cross-linking agent and a difunctional monomer unit (C) for increasing cohesive force and adjusting adhesive strength. When using the acrylic adhesive agent in the preparation of a solution, the acrylic adhesive agent is separated from an emulsion obtained by the emulsion polymerization through desalting or the like, re-dissolved in a solvent, and used. When the acrylic adhesive agent has a high molecular weight, in many cases, it does not dissolve as fully, or is not dissolved, in a solvent. Therefore, in view of the costs as well, it is preferable to use the acrylic adhesive agent in the form of an emulsion.

Examples of the monomer (A) forming the monomer unit (A) include an acrylic acid alkyl ester or a methacrylic acid alkyl ester having an alkyl group having about 1 to 12 carbon atoms (these are generally referred to as a (meth)acrylic acid alkyl ester). Preferable examples thereof include a (meth)acrylic acid alkyl ester having an alkyl group having 1 to 8 carbon atoms. Specific examples thereof include methyl acrylate, methyl methacrylate, ethyl acrylate, ethyl methacrylate, butyl acrylate, butyl methacrylate and 2-ethylhexyl acrylate. These may be used either singly or in a mixture of two or more kinds thereof Usually, the amount used of the monomer (A) is preferably contained in the range of 10 weight % to 98.9 weight % based on the total amount of all the monomers as raw materials of the adhesive agent. More preferably, it is in the range of 85 weight % to 95 weight %. By specifying the amount used of the monomer (A) in such a range, a polymer containing from 10 weight % to 98.9 weight %, and preferably from 85 weight % to 95 weight %, of the (meth)acrylic acid alkyl ester monomer unit (A) can be obtained.

Examples of the monomer (B) forming the monomer unit (B) having a functional group capable of reacting with a cross-linking agent include acrylic acid, methacrylic acid, itaconic acid, mesaconic acid, citraconic acid, fumaric acid, maleic acid, itaconic acid monoalkyl ester, mesaconic acid monoalkyl ester, citraconic acid monoalkyl ester, fumaric acid monoalkyl ester, maleic acid monoalkyl ester, glycidyl acrylate, glycidyl methacrylate, 2-hydroxyethyl acrylate, 2-hydroxyethyl methacrylate, acrylamide, methacrylamide, tertiary-butylaminoethyl acrylate, tertiary-butylaminoethyl methacrylate and the like. Preferable examples thereof include acrylic acid, methacrylic acid, 2-hydroxylethyl acrylate, 2-hydroxylethyl methacrylate, acrylamide, methacrylamide and the like. One of these may be copolymerized with the main monomer (A), or two or more kinds thereof may be copolymerized therewith. Usually, the amount used of the monomer (B) having a functional group capable of reacting with a cross-linking agent is preferably contained in the range of 1 weight % to 40 weight % based on the total amount of all the monomers as raw materials of the adhesive agent. A more preferable amount is in the range of 1 weight % to 10 weight %. Thus, a polymer having the structural unit (B) with approximately the same composition as the monomer composition can be obtained.

Since it is preferable that the adhesive agent has a storage elastic modulus of not less than 1×10⁵ Pa in the temperature range of 150° C. to 200° C., it is preferable to improve a cross-linking system and maintain a cohesive force by copolymerizing the difunctional monomer (C). Examples of the difunctional monomer (C) include allyl methacrylate, allyl acrylate, divinylbenzene, vinyl methacrylate, vinyl acrylate, a compound having a propylene glycol structure as a main chain thereof and diacrylate or dimethacrylate at both ends thereof (such as PDP-200, PDP-400, ADP-200 or ADP-400 (all trade names, manufactured by Nippon Oils and Fats Co., Ltd.)), a compound having a tetramethylene glycol structure as a main chain thereof and diacrylate or dimethacrylate at both ends thereof (such as ADT-250 or ADT-850 (both trade names, manufactured by Nippon Oils and Fats Co., Ltd.)), and a compound having a structure of a mixture thereof (such as ADET-1800 or ADPT-4000 (both trade names, manufactured by Nippon Oils and fats Co., Ltd.)) and the like.

When the difunctional monomer (C) is emulsion-copolymerized, the amount of the monomer (C) contained is preferably in the range of 0.1 weight % to 30 weight %, and more preferably in the range of 0.1 weight % to 5 weight % based on the total amount of the monomers. In this manner, a polymer containing the structural unit (C) and having a composition approximately the same as the monomer composition can be obtained.

In addition to the main monomer (A) constituting the adhesive agent and the comonomer (B) having the functional group capable of reacting with a cross-linking agent, a specific comonomer having a property as a surfactant (hereinafter referred to as a polymerizable surfactant) may be copolymerized. When the polymerizable surfactant is copolymerized with a main monomer and a comonomer for emulsion polymerization, it also serves as an emulsifying agent in emulsion polymerization. An acrylic adhesive agent prepared by emulsion polymerization using a polymerizable surfactant is preferred as contamination on the wafer surface due to a surfactant does not occur. When using a polymerizable surfactant, even when slight contamination occurs due to the adhesive agent, such contamination can easily be removed by washing the non-metal-film-formed surface with water.

Examples of the polymerizable surfactant include a compound formed by introducing a polymerizable 1-propenyl group into a benzene ring of polyoxyethylene nonylphenyl ether (trade names: AQUARON RN-10, AQUARON RN-20, AQUARON RN-30, AQUARON RN-50 and the like, manufactured by Daiichi Kogyo Seiyaku Co., Ltd.), a compound formed by introducing a polymerizable 1-propenyl group into a benzene ring of an ammonium salt of sulfuric acid ester of polyoxyethylene nonylphenyl ether (trade names: AQUARON HS-10, AQUARON HS-20 and the like, manufactured by Daiichi Kogyo Seiyaku Co., Ltd.), and a sulfosuccinic acid diester compound having a polymerizable double bond in a molecule thereof (trade names: LATEMUL S-120A, LATEMUL S-180A and the like, manufactured by Kao Corporation). Further, a monomer having a polymerizable double bond, such as vinyl acetate, acrylonitrile, styrene or the like may be copolymerized as required.

Examples of the polymerization method of the acrylic adhesive agent include radical polymerization, anionic polymerization, cationic polymerization and the like. Considering the costs of producing the adhesive agent, the influence of the functional groups of the monomers, the influence of ion contamination on the surface of the semiconductor wafer and the like, radical polymerization is preferable. Examples of the radical polymerization initiator used in the radical polymerization include organic peroxides such as benzoyl peroxide, acetyl peroxide, isobutyl peroxide, octanoyl peroxide, di-tertiary-butyl peroxide, di-tertiary-amyl peroxide or the like, inorganic peroxides such as ammonium persulfate, potassium persulfate, sodium persulfate or the like, and azo compounds such as 2,2′-azobisisobutyronitrile, 2,2′-azobis-2-methylbutyronitrile, 4,4′-azobis-4-cyanovaleric acid or the like.

When the polymerization is performed by the emulsion polymerization method, among these radical polymerization initiators, water-soluble inorganic peroxides such as ammonium persulfate, potassium persulfate, sodium persulfate or the like, and water-soluble azo compounds having a carboxyl group in a molecule, such as 4,4′-azobis-4-cyanovaleric acid or the like, are preferably used. In consideration of the ion contamination on the surface of the semiconductor wafer, ammonium persulfate and azo compounds having a carboxyl group in a molecule, such as 4,4′-azobis-4-cyanovaleric acid or the like, are more preferably used. Azo compounds having a carboxyl group in a molecule, such as 4,4′-azobis-4-cyanovaleric acid or the like are particularly preferably used.

Furthermore, examples of a method for adjusting the adhesive strength or the peeling property so that the adhesive layer fully functions as an adhesive agent even under the temperature conditions for forming the metal film include a method of cross-linking a particulate bulk so as to maintain the cohesive force of the emulsion particles.

By adding a cross-linking agent having two or more cross-linkable functional groups in a molecule to react it with the functional group of the acrylic adhesive agent, adhesive strength and cohesive force can be adjusted. Examples of the cross-linking agent include epoxy compounds such as sorbitol polyglycidyl ether, polyglycerol polyglycidyl ether, pentaerythritol polyglycidyl ether, diglycerol polyglycidyl ether, glycerol polyglycidyl ether, neopentylglycol diglycidyl ether, resorcin diglycidyl ether or the like, isocyanate compounds such as tetramethylene diisocyanate, hexamethylene diisocyanate, trimethylolpropane toluene diisocyanate 3-addition product, polyisocyanate or the like, aziridine compounds such as trimethylolpropane-tri-β-aziridinyl propionate, tetramethylolmethane-tri-β-aziridinyl propionate, N,N′-diphenylmethane-4,4′-bis(1-aziridinecarboxyamide), N,N′-hexamethylene-1,6-bis(1-azilidinecarboxyamide), N,N′-toluene-2,4-bis(1-azilidinecarboxyamide), trimethylolpropane-tri-β-(2-methylaziridine) propionate or the like, tetrafunctional epoxy compounds such as N,N,N′,N′-tetraglycidyl-m-xylenediamine or 1,3-bis(N,N′-diglycidylaminomethyl)cyclohexane, and melamine compounds such as hexamethoxymethylolmelamine or the like. These may be used either singly or in combination of two or more kinds.

Ordinarily, the cross-linking agent is preferably used in such a range that the number of functional groups in the cross-linking agent is not larger than the number of functional groups in the acrylic adhesive agent. However, when a functional group is newly generated in the cross-linking reaction or when the cross-linking reaction proceeds slowly, the cross-linking agent may be used in a larger amount as required. The preferable content of the cross-linking agent is from 0.1 parts by weight to 15 parts by weight based on 100 parts by weight of the acrylic adhesive agent. When the content is low, the cohesive force of the adhesive layer might be insufficient, the elastic modulus might be not more than 1×10⁵ Pa at 150° C. to 200° C., and heat resistance may become insufficient. As a result, an adhesive residue caused by the adhesive layer tends to easily occur. Furthermore, the adhesive strength is excessively increased. So, when the adhesive film is peeled away from the non-metal-film-formed surface, peeling trouble may occur in an automatic detaping machine and the metal-film-formed adherend might be broken in some cases. On the other hand, when the content of the cross-linking agent is high, the adhesive strength between the adhesive layer and the non-metal-film-formed surface is weakened, with the result that the adhesive layer in the step of forming a metal film is peeled away and the non-metal-film-formed surface might be contaminated in some cases.

The adhesive agent coating solution used in the present invention may appropriately contain tackifiers for adjusting adhesive properties, such as rosin resins, terpene resins and the like, and various surfactants and the like, to such an extent that the aim of the present invention is not influenced, in addition to the acrylic adhesive agent prepared by copolymerizing the specific difunctional monomer and the cross-linking agent. Moreover, when the coating solution is an emulsion, film-forming agents such as diethylene glycol monoalkyl ethers and the like may appropriately be added to such an extent that the aim of the present invention is not influenced. Diethylene glycol monoalkyl ethers and their derivatives used as film-forming agents, when they are present in large amounts in the adhesive layer, might not eliminate contamination on the non-metal-film-formed surface by washing in some cases. For this reason, it is preferable that materials which are easily volatilized as a film-forming agent are used to lower the residual amounts of these in the adhesive layer.

As a method of coating the adhesive agent coating solution on one surface of the base film or the release film, conventionally-known coating methods such as a roll coater method, a reverse roll coater method, a gravure roll method, a bar coating method, a comma coater method, a die coater method or the like can be used. The conditions for drying the coated adhesive agent are not particularly restricted. Generally, it is preferable to perform the drying in a range of 80° C. to 200° C. for 10 seconds to 10 minutes. It is more preferable to perform the drying in a range of 80° C. to 170° C. for 15 seconds to 5 minutes. For satisfactorily promoting the cross-linking reaction of the cross-linking agent and the adhesive agent, the adhesive film may be further heated at a temperature of 40° C. to 80° C. for about 5 hours to 300 hours after the drying of the adhesive agent coating solution.

### EXAMPLES

The present invention is hereinafter more specifically illustrated with reference to Examples. Meanwhile, the various properties described in the Examples were measured by the following methods.

1. Storage Elastic Modulus (Pa)

A sample for measuring a viscoelasticity is prepared using a portion of an adhesive layer of an adhesive film laminated up to a thickness of 1 mm. The sample is cut in a circle having a diameter of 8 mm. A storage elastic modulus is measured at 150° C. and 200° C. using a dynamic viscoelasticity measuring device (trade name: RMS-800 MODEL, manufactured by Rheometrics, Inc.). The measurement frequency is 1 Hz, and warpage is from 0.1% to 3%.

2. Evaluation of Contamination

A sample adhesive film is adhered to a whole surface of a silicon mirror wafer (diameter: 5 inches, thickness: 725 μm) via its adhesive layer, and a metal is formed on the back surface of the wafer under the conditions in 3. The adhesive film is then peeled away (model: HR8500II, manufactured by Nitto Seiki Corp.) and the surface of the wafer is observed with a laser focus microscope (models: VF-7510, VF-7500 and VP-ED100, manufactured by KEYENCE Corp.) at 250 times magnification. The evaluation standard is as follows.

O: No adhesive residue.

X: Adhesive residue occurs.

3. Evaluation of Formation of a Metal Film

An adhesive film-attached wafer is placed on a metal film forming device and ventilated. When the inside of the chamber reaches 10⁻⁵ Pa, film formation of Ti, Ni and Au is initiated respectively. When the time for reaching vacuum is over 30 minutes, metal film formation is not carried out and evaluation of metal film formation is marked with “X”. Furthermore, when the time for reaching vacuum is less than 30 minutes and film formation of all metals can be carried out, evaluation of metal film formation is marked with “O”.

4. Gas Transmission Rate

A sample film is allowed to stand under the conditions of temperature of 20° C., humidity of 65%, and 1 atmospheric pressure for 24 hours and then the gas transmission rate is measured according to JIS K7126.

5. Water Absorptance

A sample is immersed in pure water at 23° C. for 24 hours. The weight increment thereafter to the weight before immersion is indicated by the weight ratio.

Furthermore, the metal oxide film layer is formed according to the following method.

Silicon, titanium and aluminum are subjected to a vacuum evaporation on a base film in the presence of oxygen to form an oxide film. The oxide film is formed to have a thickness of 10 nm.

### Example 1

An adhesive layer (20 μm) having a storage elastic modulus of 5.5×10⁵ Pa at 150° C. was formed on a surface of a polyethyleneterephthalate film (thickness: 50 82 m, gas transmission rate: 4.8 cc/m²·day·atm, water absorptance: 0.05 weight %) having, on another surface thereof, a 10-nm aluminum oxide film layer, so as to prepare an adhesive film 1.

The adhesive layer was formed by using an adhesive agent in which 5.0 parts by weight of a cross-linking agent (polyglycerol polyglycidyl ether) was added to 100 parts by weight of an emulsion copolymer comprising 5.0 weight % of a functional monomer forming a cross-linking point with a cross-linking agent, 5.0 weight % of a difunctional monomer (ADET-1800) which controls the cohesive force among particles and 90 weight % of an acrylic acid ester (methyl methacrylate, butyl acrylate and 2-ethylhexyl acrylate).

The adhesive layer 1 was attached to the silicon mirror wafer, and metal films made of Ti, Ni or Au were formed respectively. Each metal film was formed under a pressure of not more than 10-5 Pa and at a temperature range of 120° C. to 150° C. in a chamber. The Ni film was formed at a slightly higher temperature. After the formation of the metal film, the adhesive film 1 was peeled away and the contamination on the silicon mirror wafer was evaluated. The results are shown in Table 1.

### Example 2

A base film was formed by laminating an ethylene-vinyl acetate copolymer film (thickness: 120 μm) onto a surface of a polyethyleneterephthalate film (thickness: 50 μm, gas transmission rate: 4.8 cc/m²·day·atm, water absorptance: 0.05 weight %) having, on another surface thereof, a 10-nm aluminum oxide film layer. Then, an adhesive layer (20 μm) having a storage elastic modulus of 5.5×10⁵ Pa at 150° C. was formed on a side of the ethylene-vinyl acetate copolymer layer so as to prepare an adhesive film 2.

The adhesive layer was formed by using the same adhesive agent as that used in Example 1.

A metal film was formed by the same method as in Example 1. The obtained results are shown in Table 1.

### Example 3

A laminate film was formed by laminating a polyethylene film (thickness: 50 μm) onto a surface of a polyethyleneterephthalate film (thickness: 50 μm, gas transmission rate: 4.8 cc/m²·day·atm, water absorptance: 0.05 weight %) having, as another surface thereof, a 10-nm aluminum oxide film layer formed thereon. Then, an adhesive layer (20 μm) having a storage elastic modulus of 5.5×10⁵ Pa at 150° C. was formed on a side of the polyethylene film to prepare an adhesive film 3.

The adhesive layer was formed by using the same adhesive agent as that used in Example 1.

A metal film was formed by the same method as in Example 1. The obtained results are shown in Table 1.

### Example 4

An adhesive layer (20 μm) having a storage elastic modulus of 5.5×10⁵ Pa at 150° C. was formed on a surface of a polyethyleneterephthalate film (thickness: 50 μm, gas transmission rate: 4.65 cc/m²·day·atm, water absorptance: 0.05 weight %) having, on another surface thereof, a 10-nm titanium oxide film layer, so as to prepare an adhesive film 4.

The adhesive layer was formed by using the same adhesive agent as that used in Example 1.

A metal film was formed by the same method as in Example 1. The obtained results are shown in Table 1.

### Example 5

An adhesive layer (20 μm) having a storage elastic modulus of 5.5×10⁵ Pa at 150° C. was formed on a surface of a polyethyleneterephthalate film (thickness: 50 μm, gas transmission rate: 0.80 cc/m²·day·atm, water absorptance: 0.05 weight %) having, on another surface thereof, a 10-nm silicon oxide film layer, so as to prepare an adhesive film 5.

The adhesive layer was formed by using the same adhesive agent as that used in Example 1.

A metal film was formed by the same method as in Example 1. The obtained results are shown in Table 1.

### Example 6

An adhesive layer (20 μm) having a storage elastic modulus of 5.5×10⁵ Pa at 150° C. was formed on a liquid crystalline polymer film (registered trademark: VECSTAR, manufactured by Kuraray Co., Ltd., thickness: 50 μm, gas transmission rate: 0.30 cc/m²·day·atm, water absorptance: 0.04 weight %) so as to prepare an adhesive film 6.

The adhesive layer was formed by using the same adhesive agent as that used in Example 1.

A metal film was formed by the same method as in Example 1. The obtained results are shown in Table 1.

### Example 7

A base film was formed by laminating an ethylene-vinyl acetate copolymer film (thickness: 120 μm) onto a liquid crystalline polymer film (registered trademark: VECSTAR, manufactured by Kuraray Co., Ltd., thickness: 50 μm, gas transmission rate: 0.30 cc/m²·day·atm, water absorptance: 0.04 weight %). Then, an adhesive layer (20 μm) having a storage elastic modulus of 5.5×10⁵ Pa at 150° C. was formed on a surface of the ethylene-vinyl acetate copolymer film of the base film so as to prepare an adhesive film 7. The adhesive layer was formed by using the same adhesive agent as that used in Example 1.

An evaluation was conducted by the same method as in Example 1. The obtained results are shown in Table 1.

### Example 8

A base film was formed by laminating, onto a liquid crystalline polymer film (registered trademark: VECSTAR, manufactured by Kuraray Co., Ltd., thickness: 50 μm, gas transmission rate: 0.30 cc/m²·day·atm, water absorptance: 0.04 weight %), a polyethyleneterephthalate film (thickness: 50 μm) and an ethylene-vinyl acetate copolymer film (thickness: 120 μm) in this order. Then, an adhesive layer (20 μm) having a storage elastic modulus of 5.5×10⁵ Pa at 150° C. was formed on a surface of the ethylene-vinyl acetate copolymer film of the base film so as to prepare an adhesive film 8. The adhesive layer was formed by using the same adhesive agent as that used in Example 1.

An evaluation was conducted by the same method as in Example 1. The obtained results are shown in Table 1.

### Example 9

A base film was formed by laminating, onto a liquid crystalline polymer film (registered trademark: VECSTAR, manufactured by Kuraray Co., Ltd., thickness: 50 μm, gas transmission rate: 0.30 cc/m²·day·atm, water absorptance: 0.04 weight %), a polyethylenenaphthalate film (thickness: 50 μm) and an ethylene-vinyl acetate copolymer film (thickness: 120 μm) in this order. Then, an adhesive layer (20 μm) having a storage elastic modulus of 5.5×10⁵ Pa at 150° C. was formed on a surface of the ethylene-vinyl acetate copolymer film of the base film so as to prepare an adhesive film 9. The adhesive layer was formed by using the same adhesive agent as that used in Example 1. An evaluation was conducted by the same method as in Example 1. The obtained results are shown in Table 1.

### Example 10

An adhesive layer (20 μm) having a storage elastic modulus of 5.5×10⁵ Pa at 150° C. was formed on a base film formed by laminating a polyethylene film (thickness: 50 μm) onto a liquid crystalline polymer film (registered trademark: VECSTAR, manufactured by Kuraray Co., Ltd., thickness: 50 μm, gas transmission rate: 0.30 cc/m²·day·atm, water absorptance: 0.04 weight %) so as to prepare an adhesive film 10. The adhesive layer was formed by using the same adhesive agent as that used in Example 1.

An evaluation was conducted by the same method as in Example 1. The obtained results are shown in Table 1.

### Example 11

An adhesive layer (20 μm) having a storage elastic modulus of 5.5×10⁵ Pa at 150° C. was formed on a liquid crystalline polymer film (registered trademark: VECSTAR, manufactured by Kuraray Co., Ltd., thickness: 100 μm, gas transmission rate: 0.95 cc/m²·day·atm, water absorptance: 0.04 weight %) so as to prepare an adhesive film 11. The adhesive layer was formed by using the same adhesive agent as that used in Example 1.

An experiment was carried out by the same method as in Example 1. The obtained results are shown in Table 1.

### Example 12

An adhesive layer (20 μm) having a storage elastic modulus of 5.5×10⁵ Pa at 150° C. was formed on a liquid crystalline polymer film (registered trademark: VECSTAR, manufactured by Kuraray Co., Ltd., thickness: 50 μm, gas transmission rate: 0.35 cc/m²·day·atm, water absorptance: 0.95 weight %) so as to prepare an adhesive film 12. The adhesive layer was formed by using the same adhesive agent as that used in Example 1.

An evaluation was carried out by the same method as in Example 1. The obtained results are shown in Table 1.

### Comparative Example 1

An adhesive layer (20 μm) having a storage elastic modulus of 5.5×10⁵ Pa at 150° C. was formed on a polyethyleneterephthalate film (thickness: 50 μm, gas transmission rate: 50 cc/m²·day·atm, water absorptance: 0.05 weight %) on which no oxide layer was formed so as to prepare an adhesive film 13. The adhesive layer was formed by using the same adhesive agent as that used in Example 1. A metal film was formed by the same method as in Example 1. The obtained results are shown in Table 2.

### Comparative Example 2

An adhesive layer (20 μm) having a storage elastic modulus of 5.5×10⁵ Pa at 150° C. was formed on a surface of a polyethyleneterephthalate film (thickness: 50 μm, gas transmission rate: 5.3 cc/m²·day·atm, water absorptance: 0.05 weight %) having, on another surface thereof, a 10-nm aluminum oxide film layer, so as to prepare an adhesive film 14. The adhesive layer was formed by using the same adhesive agent as that used in Example 1. A metal film was formed by the same method as in Example 1. The obtained results are shown in Table 2.

### Comparative Example 3

A base film was formed by laminating an ethylene-vinyl acetate copolymer film (thickness: 120 μm, gas transmission rate: 40 cc/m²·day·atm) onto a polyethyleneterephthalate film (thickness: 50 μm, gas transmission rate: 50 cc/m²·day·atm, water absorptance: 0.05 weight %). Then, an adhesive layer (20 μm) having a storage elastic modulus of 5.5×10⁵ Pa at 150° C. was formed on a side of the ethylene-vinyl acetate copolymer layer of the base film so as to prepare an adhesive film 15. The adhesive layer was formed by using the same adhesive agent as that used in Example 1. A metal film was formed by the same method as in Example 1. The obtained results are shown in Table 2.

### Comparative Example 4

A polyethyleneterephthalate film (thickness: 50 μm, gas transmission rate: 50 cc/m²·day·atm, water absorptance: 0.05 weight %) was laminated with a polyethylene film (thickness: 50 μm, gas transmission rate: 6.0 cc/m²·day·atm). Then, an adhesive layer (20 μm) having a storage elastic modulus of 5.5×10⁵ Pa at 150° C. was formed on a side of the polyethylene film so as to prepare an adhesive film 16. The adhesive layer was formed by using the same adhesive agent as that used in Example 1. A metal film was formed by the same method as in Example 1. The obtained results are shown in Table 2.

### Comparative Example 5

An adhesive layer (20 μm) having a storage elastic modulus of 5.5×10⁵ Pa at 150° C. was formed on a polyimide film (thickness: 50 μm, gas transmission rate: 490 cc/m²·day·atm, water absorptance: 2.0 weight %) so as to prepare an adhesive film 17. The adhesive layer was formed by using the same adhesive agent as that used in Example 1. An experiment was carried out by the same method as in Example 1. The obtained results are shown in Table 2.

### Comparative Example 6

An adhesive layer (20 μm) having a storage elastic modulus of 5.5×10⁵ Pa at 150° C. was formed on a polyphenylenesulfide film (thickness: 50 μm, gas transmission rate: 250 cc/m²·day·atm, water absorptance: 0.1 weight %) so as to prepare an adhesive film 18. The adhesive layer was formed by using the same adhesive agent as that used in Example 1. An experiment was carried out by the same method as in Example 1. The obtained results are shown in Table 2.

### Comparative Example 7

An adhesive layer (20 μm) having a storage elastic modulus of 5.5×10⁵ Pa at 150° C. was formed on a polypropylene film (thickness: 50 μm, gas transmission rate: 2,000 cc/m²·day·atm, water absorptance: 0.8 weight %) so as to prepare an adhesive film 19. The adhesive layer was formed by using the same adhesive agent as that used in Example 1. An experiment was carried out by the same method as in Example 1. The obtained results are shown in Table 2.

TABLE 1

| | | Example 1 | Example 2 | Example 3 | Example 4 | Example 5 | Example 6 |
|---|---|---|---|---|---|---|---|
| Metal of Metal oxide film | | Aluminum | Aluminum | Aluminum | Titanium | Silicon | — |
| Thickness of Metal oxide film | | 10 | 10 | 10 | 10 | 10 | |
| [nm] | | | | | | | |
| Structure of Base | A | Polyethylene | Polyethylene | Polyethylene | Polyethylene | Polyethylene | VECSTAR |
| film | | terephthalate | terephthalate | terephthalate | terephthalate | terephthalate | |
| | B | | Ethylene-vinyl | Polyethylene | | | |
| | | | acetate copolymer | | | | |
| Gas transmission rate of Layer A | | 4.8 | 4.8 | 4.8 | 4.65 | 0.8 | 0.30 |
| [cc/m² · day · atm] | | | | | | | |
| Elastic modulus of Adhesive agent | | 5.5 × 10⁵ | 5.5 × 10⁵ | 5.5 × 10⁵ | 5.5 × 10⁵ | 5.5 × 10⁵ | 5.5 × 10⁵ |
| [Pa] | | | | | | | |
| Metal film formation | | ◯ | ◯ | ◯ | ◯ | ◯ | ◯ |
| Contamination | | ◯ | ◯ | ◯ | ◯ | ◯ | ◯ |
| | | Example 7 | Example 8 | Example 9 | Example 10 | Example 11 | Example 12 |
| Metal of Metal oxide film | | — | — | — | — | — | — |
| Structure | A | VECSTAR | VECSTAR | VECSTAR | VECSTAR | VECSTAR | VECSTAR |
| of Base | B | Ethylene-vinyl | Polyethylene | Polyethylene | Polyethylene | | |
| film | | acetate copolymer | terephthalate | naphthalate | | | |
| | C | | Ethylene-vinyl | Ethylene- | | | |
| | | | acetate | vinyl acetate | | | |
| | | | copolymer | copolymer | | | |

| | | | | | | |
|---|---|---|---|---|---|---|
| Gas transmission rate of Layer A | 0.30 | 0.30 | 0.30 | 0.30 | 0.95 | 0.35 |
| [cc/m² · day · atm] | | | | | | |
| Water absorptance of Layer A [%] | 0.04 | 0.04 | 0.04 | 0.04 | 0.04 | 0.95 |
| Elastic modulus of Adhesive agent | 5.5 × 10⁵ | 5.5 × 10⁵ | 5.5 × 10⁵ | 5.5 × 10⁵ | 5.5 × 10⁵ | 5.5 × 10⁵ |
| [Pa] | | | | | | |
| Metal film forming | ◯ | ◯ | ◯ | ◯ | ◯ | ◯ |
| Contamination | ◯ | ◯ | ◯ | ◯ | ◯ | ◯ |

TABLE 2

| | | Comparative | Comparative | Comparative | Comparative |
|---|---|---|---|---|---|
| | | Example 1 | Example 2 | Example 3 | Example 4 |
| Metal of Metal oxide film | | — | Aluminum | — | — |
| Thickness of Metal oxide | | — | 10 | — | — |
| film [nm] | | | | | |
| Structure of | A | Polyethylene | Polyethylene | Polyethylene | Polyethylene |
| Base film | | terephthalate | terephthalate | terephthalate | terephthalate |
| | B | | | Ethylene-vinyl | Polyethylene |
| | | | | acetate | |
| | | | | copolymer | |

| | | | | |
|---|---|---|---|---|
| Gas transmission rate of | 50 | 5.3 | 50 | 50 |
| Layer A [cc/m² · day · atm] | | | | |
| Elastic modulus of | 5.5 × 10⁵ | 5.5 × 10⁵ | 5.5 × 10⁵ | 5.5 × 10⁵ |
| Adhesive agent [Pa] | | | | |
| Metal film formation | X | X | X | X |
| Contamination | — | — | — | — |

| | Comparative | Comparative | Comparative |
|---|---|---|---|
| | Example 5 | Example 6 | Example 7 |
| Metal of Metal oxide film | — | — | — |
| Structure of Base film | Polyimide | Polyphenylene | Polypropylene |
| | | sulfide | |
| Gas transmission rate of Base | 490 | 250 | 2,000 |
| film [cc/m² · day · atm] | | | |
| Water absorptance of Base film | 2.0 | 0.1 | 0.8 |
| [%] | | | |
| Elastic modulus of Adhesive | 5.5 × 10⁵ | 5.5 × 10⁵ | 5.5 × 10⁵ |
| agent [Pa] | | | |
| Metal film Formation | X | X | X |
| Contamination | — | — | — |

### INDUSTRIAL APPLICABILITY

The present invention relates to an adhesive film which can prevent damage to a non-metal-film-formed surface and also reduce contamination on the wafer surface at the time of forming a metal film of a semiconductor wafer. By protecting the non-metal-film-formed surface with an adhesive film of the present invention, a washing step using a solvent in a step of manufacturing semiconductors can be omitted and contamination on the non-metal-film-formed surface can also be reduced, thereby resulting in enhancement of productivity and workability. Thus, the present invention is an industrially advantageous invention.

1. A method for forming a metal film on a non-circuit-formed surface of a semiconductor wafer, wherein a metal film is formed by applying an adhesive film, comprising an adhesive layer formed on one surface of a base film comprising at least one film layer having a gas transmission rate of not more than 49.35 ml/m²·day/MPa, to a circuit-formed surface of a semiconductor wafer (a non-metal-film-formed surface).

2. The method for forming a metal film on a non-circuit-formed surface of a semiconductor wafer according to claim 1, wherein the base film comprises a metal film layer or a metal oxide film layer, and at least one film layer having a gas transmission rate of not more than 49.35 ml/m²·day/MPa.

3. The method for forming a metal film on a non-circuit-formed surface of a semiconductor wafer according to claim 1, wherein the base film comprises at least one film layer having a gas transmission rate of not more than 9.87 ml/m²·day/MPa and water absorptance of not more than 1.0 weight %.

4. The method for forming a metal film on a non-circuit-formed surface of a semiconductor wafer according to claim 1, wherein the base film further comprises one film layer selected from an ethylene-vinyl acetate copolymer film, a polyester film and a polyethylene film.

5. The method for forming a metal film on a non-circuit-formed surface of a semiconductor wafer according to claim 1, wherein the adhesive layer has a storage elastic modulus of not less than 1×10⁵ Pa at 150° C.

6. An adhesive film for forming a metal film on a non-circuit-formed surface of a semiconductor wafer, comprising an adhesive layer formed on one surface of a base film comprising at least one film layer having a gas transmission rate of not more than 49.35 ml/m²·day/MPa.

7. An adhesive film for forming a metal film on a non-circuit-formed surface of a semiconductor wafer, comprising an adhesive layer formed on one surface of a base film comprising at least one film layer having a gas transmission rate of not more than 9.87 ml/m²·day/MPa and water absorptance of not more than 1.0 weight %.

8. The method for forming a metal film on a non-circuit-formed surface of a semiconductor wafer according to claim 2, wherein the base film further comprises one film layer selected from an ethylene-vinyl acetate copolymer film, a polyester film and a polyethylene film.

9. The method for forming a metal film on a non-circuit-formed surface of a semiconductor wafer according to claim 3, wherein the base film further comprises one film layer selected from an ethylene-vinyl acetate copolymer film, a polyester film and a polyethylene film.

10. The method for forming a metal film on a non-circuit-formed surface of a semiconductor wafer according to claim 2, wherein the adhesive layer has a storage elastic modulus of not less than 1×10⁵ Pa at 150° C.

11. The method for forming a metal film on a non-circuit-formed surface of a semiconductor wafer according to claim 3, wherein the adhesive layer has a storage elastic modulus of not less than 1×10⁵ Pa at 150° C.
